(19) United States
(12) Patent Application Publication
(10) Pub. No.: US 2025/0337379 A1
(43) Pub. Date: Oct. 30, 2025

(54) Programmable Gain Amplifier Having a Resistor Ladder with Multiple Current Paths

(71) Applicant: TEXAS INSTRUMENTS INCORPORATED, Dallas, TX (US)

(72) Inventors: Kunal Karanjkar, Bangalore (IN); Nitin Agarwal, Bangalore (IN); Nikhil Das, Bangalore (IN)

(21) Appl. No.: 18/649,786

(22) Filed: Apr. 29, 2024

(51) Int. Cl. H03G 3/00; H03F 3/45; H03G 1/00

(52) U.S. Cl. CPC H03G 3/001; H03F 3/45475; H03G 1/0088; H03F 2203/45528

(57) ABSTRACT

A programmable gain amplifier (PGA) architecture provides for robust operation over a bandwidth and for a multitude of gain settings. For instance, the PGA architecture may include multiple switches to implement different current paths by bypassing resistors in a resistor ladder. The different current paths may result in different gain settings. In some implementations, the switches may be used to hold a value of RA constant while a value of RB may be varied over the different gain settings, where gain may be inferred from the equation Vout=Vin*(1+RB/RA).

### TECHNICAL FIELD

The present description relates generally to programmable gain amplifiers and, more specifically, to resistor ladder and switching arrangements for use in programmable gain amplifiers.

### BACKGROUND

A programmable gain amplifier may include an operational amplifier (op amp) arranged to have a feedback loop with a tap point of a resistor ladder. For instance, the op amp may include an inverting input, a noninverting input, and an amplifier output. The noninverting input receives an input voltage (Vin), and the inverting input is configured to receive feedback from the tap point in the resistor ladder. For instance, the resistive portion between the amplifier output and the tap point may be referred to as RB, and the resistive portion between the tap point and ground may be referred to as RA. The noninverting gain is given by Equation 1:

$$Vout = Vin * ( 1 + RB / RA ) \qquad Eq . 1$$

Current programmable gain amplifier designs may include switches that introduce nonlinear error. Nonlinear error may present challenges when applying programmable gain to a signal that may vary over a relatively wide bandwidth.

There is a need in the art for improved programmable gain amplifier architectures and methods for use thereof.

### SUMMARY

In one example, a programmable gain amplifier includes: an amplifier having an inverting input, a noninverting input, and an amplifier output; a set of resistors coupled between a first node and a second node, wherein the first node is coupled to the amplifier output; a first switch coupled between the second node and ground; a first current path between a third node in the set of resistors and a tap point, the first current path including a second switch; and a second current path between a fourth node in the set of resistors and the tap point, the second current path including a third switch; a feedback path coupled between the tap point of the set of resistors and the inverting input of the amplifier; wherein the set of resistors includes a first resistor coupled between the third node and the fourth node.

In another example, a circuit includes: a set of resistors coupled in series having a first node coupled to an amplifier output and a second node coupled to ground; a feedback path coupling a tap point of the set of resistors to an amplifier input; and a first switch, a second switch, and a third switch, wherein: the first switch is coupled between the second node of the set of resistors and the ground, a first current path is coupled between a third node of the set of resistors and the tap point, the first current path including the second switch, wherein the first current path is parallel to a first portion of the set of resistors, a second current path is coupled between a fourth node in the set of resistors and the tap point, the second current path including the third switch, wherein the second current path is parallel to a second portion of the set of resistors, and the set of resistors includes a first resistor coupled between the third node and the fourth node.

In yet another example, an amplifier having a noninverting input, an inverting input, and an amplifier output; a set of resistors coupled in series between the amplifier output and ground; a plurality of switches; and a control circuit coupled to the plurality of switches, wherein the control circuit is further configured to: control a first switch, of the plurality of switches, to complete a first current path from a first node in the set of resistors ladder to a tap point, wherein the tap point divides a first resistive portion (RA) of the set of resistors between the tap point and ground and a second resistive portion (RB) of the set of resistors between the tap point and the amplifier output; control a second switch, of the plurality of switches, to complete a second current path from a second node in the set of resistors to the tap point; and change a sum of resistance of RA plus resistance of RB by turning on the first switch and turning off the second switch and by turning off the first switch and turning on the second switch.

### BRIEF DESCRIPTION OF THE DRAWINGS

Having thus described the invention in general terms, reference will now be made to the accompanying drawings, wherein:

FIG. 1 is an illustration of an example system, for providing programmable gain settings, according to various embodiments.

FIG. 2 is an illustration of an example use case of the system of FIG. 1, according to various embodiments.

FIG. 3 is an illustration of an example system, for providing programmable gain settings, according to various embodiments.

FIG. 4 is an illustration of an example architecture for implementing the switch S1, according to various embodiments.

FIG. 5 is an illustration of an example architecture for implementing the switches S2 and/or S3, according to various embodiments.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Various embodiments are directed to programmable gain amplifier (PGA) architectures that are intended to support both non-inverting and inverting gains with a gain error smaller than, e.g., 1%. For instance, some embodiments may provide a selectable gain from a large set of possible inverting and noninverting gains. For example, some such embodiments may provide a noninverting gain from a set of 1, 2, 4, 8, 16, and 32 over a bandwidth of approximately 10 MHz. Similarly, some such embodiments may provide an inverting gain from a set of −1, −3, −7, −15, and −31 across a similar bandwidth.

One challenge with current systems is that switches may be used to select between the various inverting and noninverting gain(s), such as at one end of a resistor ladder and between ground and an additional supply voltage (Vin2). The switches can be used to select either ground or the additional supply voltage Vin2. However, those switches may add nonlinear error to the PGA. For instance, the switches may be implemented using transistors, where those transistors may provide different impedances based on process, temperature, operating voltage, and the like. The impedance of a transistor may be large enough in some instances to cause an error greater than 1% or so, which may be undesirable and noticeable in some applications.

One way to ameliorate transistor nonlinearity may be to use large transistors. For instance, the transistors may be large in a dimension such as width and may include, e.g., a relatively large number of fins or other structures. A general rule is that larger transistors have less impedance, so larger transistors in the switches may lead to a lower error. However, larger transistors may result in larger semiconductor die area to accommodate those transistors, perhaps even overtaking a space budget for the design.

Yet another way to ameliorate transistor nonlinearity may be to use larger resistance values for RA and RB in Equation 1. However, a resistor feedback pole (P_{fb}) may cause unwanted performance. The resistor feedback pole is given by Equation 2.

$${P}_{fb} = 1 / ( ( RA ‖ RB ) * Cg ) \qquad Eq . 2$$

In Equation 2, Cg is a parasitic capacitance at the inverting input of the op amp. It may be desirable to keep the parallel resistance sum of R^{A} and RB (i.e., RA|RB) small enough that the P_{fb} is larger than the bandwidth. However, such constraint may be difficult when using large resistors at lower gain settings.

Various embodiments provide more robust architectures, including parallel current paths implemented using switches at various points in the resistor ladder. During use, a control circuit may cause a desired gain setting by selecting a parallel current path, thereby bypassing at least one of the resistors in the resistor ladder. Bypassing one or more of the resistors in the resistor ladder may result in adjusting a value of RB across gain settings while, in some instances, keeping a value of RA the same. Thus, the sum of RA plus RB may vary over gain settings. The sum of RA plus RB is the divisor in the parallel resistance sum of RA plus RB; thus, adjusting a value of RB across gain settings may allow the system to keep the resistor feedback pole at a value larger than the bandwidth. As a result, various embodiments may implement relatively large resistors to overcome or at least ameliorate nonlinearity in the switches.

According to one implementation, a programmable gain amplifier includes an amplifier having an inverting input, a noninverting input, and amplifier output. A resistor ladder may have a first end coupled to the amplifier output and a second end coupled to ground via a first switch. A feedback path may couple a tap point of the resistor ladder to the inverting input of the amplifier. A first current path may couple a first point in the resistor ladder to the tap point. The first current path may include a second switch, and the first current path may be parallel to a first portion of the resistor ladder. Further, a second current path may couple a second point in the resistor ladder to the tap point. The second current path may include a third switch, and the second current path may be parallel to a second portion of the resistor ladder. Continuing with the example, the first point in the resistor ladder may be disposed between the first end and the tap point, and the second point in the resistor ladder may be disposed between the first point in the tap point.

A control circuit may control the state of one or more switches at a given time, turning the one or more switches on and turning others of the switches off to select a desired gain setting. For instance, the control circuit may turn on the second switch and turn off the third switch to use the first current path. The first current path may bypass the first resistive portion of the resistor ladder, thereby implementing a first desired gain setting. Similarly, the control circuit may turn on the third switch and turn off the second switch to use the second current path, thereby implementing a second desired gain setting. Furthermore, a resistive portion having a resistive value RB in Equation 1 may be different between the two gain settings.

Various embodiments may provide advantages over prior solutions. For instance, various embodiments may allow for smaller nonlinearity errors, even when using relatively small transistors, by virtue of using relatively large resistors. As a result, reduced nonlinearity may provide greater precision at a lower cost. Furthermore, various embodiments may allow for adjusting a feedback pole value to maintain desired gain throughout a particular bandwidth.

The examples herein may provide specific values for resistance, gain, bandwidth, transistor dimensions, and the like. It is to be understood that those examples are for illustration, and the concepts described herein may be adapted to other applications having different particular values. In other words, the scope of implementations is not limited to any specific values discussed herein.

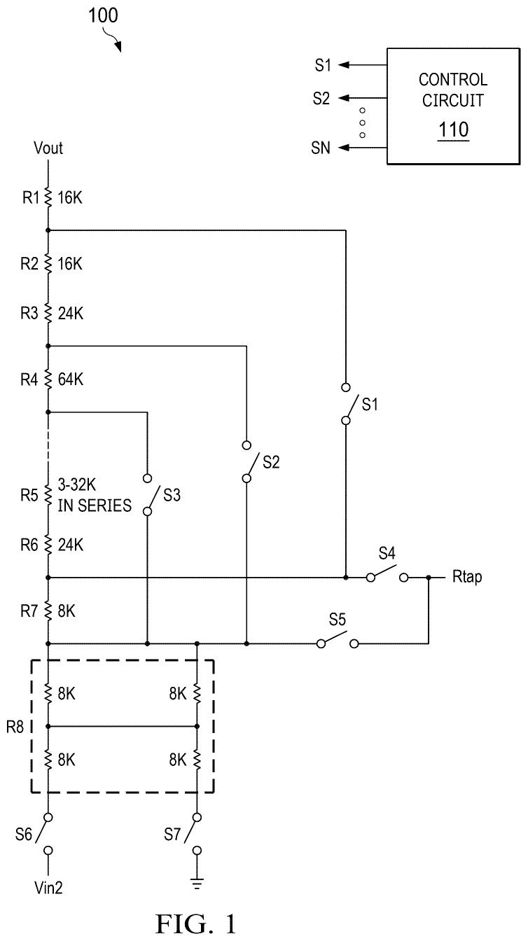

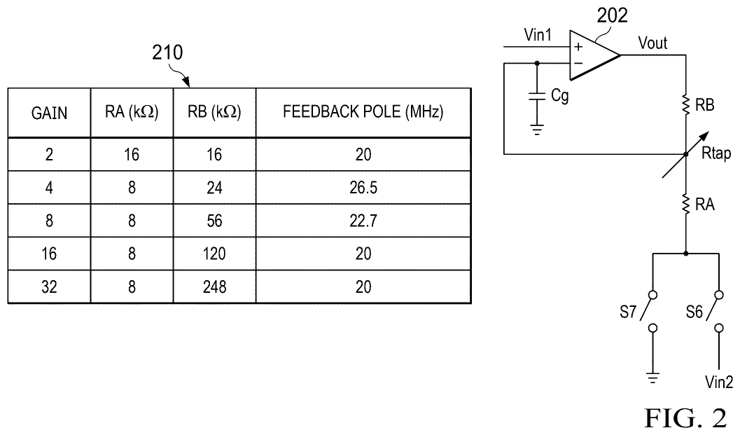

FIG. 1 is an illustration of an example system 100, for providing programmable gain settings, according to various embodiments. FIG. 2 is an illustration of an example use case of system 100, according to various embodiments. System 100 includes a resistor ladder, which includes resistors R1-R8. Example resistance values are provided, and these are not intended to be limiting. The specific resistance values in a given embodiment may vary from those of FIG. 1 based on the desired sets of gains and/or any other suitable reason.

Resistor R8 is illustrated as four different resistors but is referred to as R8 for convenience. In this example, R8 has a resistance value of 8K ohms. Resistor R5 is illustrated as a single resistor for convenience, though in some instances it may be implemented as three different resistors in series.

System 100 also includes switches S1-S7. Control circuit 110 is configured to provide control signals to open and close the various switches S1-S7 to provide desired gain settings. For instance, control circuit 110 may increase or decrease a gain level to provide a desired signal amplitude at the voltage output node Vout. Put another way, control circuit 110 may control the resistance between Vout and Rtap (RB in FIG. 2) and control the resistance between Rtap and either Vin2 or ground (RA in FIG. 2), which in turn causes the amplifier 202 (FIG. 2) to change the voltage at Vout. Control circuit 110 may be implemented in hardware logic, as firmware, or as software.

Although not shown herein, the voltage output node Vout may be coupled to an amplifier output, such as is illustrated in FIG. 2 with respect to op amp 202. In other words, at one end, the resistor ladder is coupled to an amplifier output, and the other end is coupled to either ground or a second reference voltage Vin2 via switches S7 and S6, respectively.

Switches S4 and S5 may be opened or closed by the control circuit 110 to place the tap point (Rtap) on one side or the other of resistor R7. The switches S1-S3 may be controlled by the control circuit 110 to provide one or more current paths to bypass various ones of the resistors in the resistor ladder.

The simplified circuit diagram of FIG. 2 illustrates an architecture that may be useful in analyzing the gain settings of system 100. For instance, the individual resistors between the node Vout and the tap point Rtap, to the extent those individual resistors are not bypassed, are parts of the resistive portion RB. For example, resistive portion RB may include a combination of R1, R2, R3, R4, R5, R6, and/or R7. The individual resistors between the tap point Rtap and either ground or the second reference voltage Vin2 are parts of the resistive portion RA. For example, resistive portion RA may include a combination of R7 and/or R8. For the gain settings of FIG. 1, the resistive value of the resistive portion RA changes from a gain setting of two to a gain setting of four but remains the same throughout the gain settings 4-32. By contrast, the resistive value of the resistive portion RB changes in each of the different gain settings 2-32.

For a noninverting gain of two, the control circuit 110 would turn switch S1 on, turn S4 on, and turn S7 on. The other switches may be turned off. As a result, the current path goes from the amplifier output at Vout, through R1, S1, R7, R8, and S7. Thus, the resistive portion RB is made up of R1 (16 K ohms), and the resistive portion RA is made up of R7-R8 (16 K ohms total). Resistors R2-R6 are bypassed. As noted in table 210, that provides a feedback pole of 20 MHz, which is larger than a bandwidth of 10 MHz.

For a gain of four, the control circuit 110 controls the switches so that switch S1 is on, as are switches S5 and S7. The current path goes from the amplifier output at Vout, through R1, S1, R7, R8, and S7. Resistors R2-R6 are bypassed. The resistive portion RB is made up of R1 and R7, and the resistive portion RA is made up of R8. Table 210 shows a feedback pole of 26.5 MHz. A difference between gain of two and gain of four is the placement of the tap point Rtap either above R7 or below R7.

For a gain of eight, the control circuit 110 controls the switches so that S2 is on, as are S5 and S7. The other switches may be turned off. The current path goes from Vout through resistors R1-R3, R8, and switch S7. Resistors R4-R7 are bypassed. The resistive portion RB is made up of R1-R3, and the resistive portion RA is made up of R8. As illustrated in table 210, a difference between gain of four and gain of eight is the resistive value of RB, whereas the resistive value of RA stays the same.

For a gain of 16, switch S3 is turned on, as are S5 and S7. The other switches may be turned off. The current path goes from Vout through resistors R1-R4, R8, and S7. Resistors R5-R7 are bypassed. The resistive value of RB is different between the gain settings 4-16, whereas the resistive value of RA stays at 8K ohms.

For a gain of 32, switches S5 and S7 are turned on, and the other switches may be turned off. The current path goes from Vout through resistors R1-R8 and switch S7. For a gain of 32, none of the resistors are bypassed. The resistive value of RB is different between the gain settings 4-32, whereas the resistive value of RA stays at 8K ohms.

As the control circuit 110 selects the different gain settings 2-32, the sum of the resistive values RA plus RB changes from setting to setting. Depending on the particular bandwidth desired, the system 100 may be adapted to use individual ones of the resistors to satisfy Equation 2 with a feedback pole larger than the desired bandwidth.

Of course, those are the noninverting gain settings. The architecture of system 100 may be used to provide inverting gain settings as well. For instance, the first reference voltage Vin1 may be set to a value of zero, and the second reference voltage Vin2 may be set to a positive non-zero value. In such instances, the control circuit 110 may turn on S6 and turn off S7. For such use cases, a gain setting is given by Equation 3, where the switches may provide a value of RA and RB as discussed above.

$$Vout = Vin 2 * ( - RB / RA ) \qquad Eq . 3$$

For the inverting gain settings, the same switching patterns for S1-S5, as described above, may be used to bypass the same individual ones of the resistors. However, the inverting gain settings use current paths that go from Vout, through some subset of the resistors, switch S6, and Vin2. The same feedback pole benefits apply for the inverting gain settings, as for the noninverting gain settings. Additionally, various embodiments may employ appropriately sized transistors for switches S1-S7, so as not to undesirably use silicon die area budget, but also include nonlinearities that are relatively small when compared to the resistive values of the non-bypass resistors. Note that these examples use Vout to refer to a node as well as to a voltage level at that node.

In some instances, S1 may be sized to be larger than S2 or S3 because S1 sees much smaller resistance—R1,R7,R8 in series-compared to S2 or S3. However, when S1 is turned off, its relatively large size may lead to a greater amount of leakage current. The leakage current would normally be expected to traverse from the tap point Rtap to the amplifier output at node Vout, thereby corrupting the output voltage to some extent. Accordingly, some embodiments may provide a separate resistor ladder for S1.

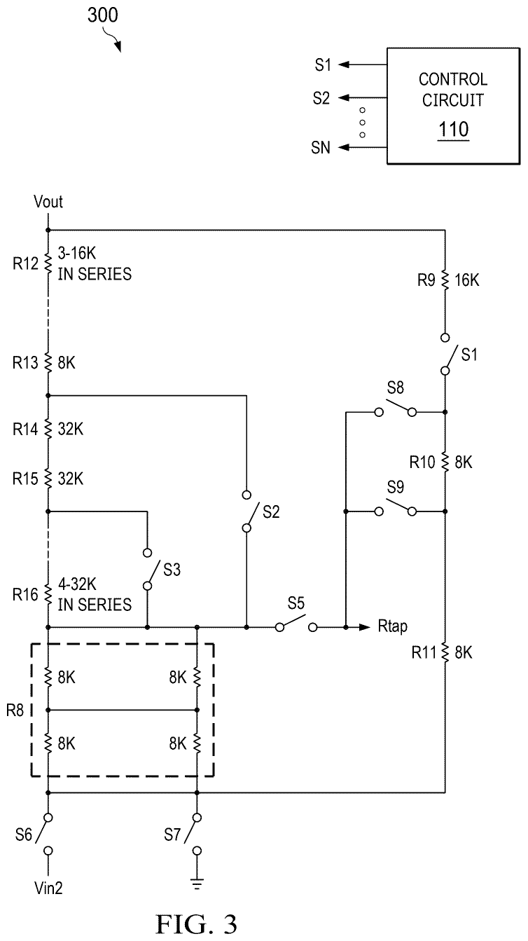

FIG. 3 is an illustration of example system 300, for providing programmable gain settings, according to various embodiments. Example resistance values are provided, and these are not intended to be limiting. The specific resistance values in a given embodiment may vary from those of FIG. 3 based on the desired sets of gains and/or any other suitable reason.

In system 300, switch S1 is given its own separate resistor ladder, which includes resistors R9-R11. When S1 is turned off, S8 and S9 are also turned off, thereby creating a path for the leakage current from switch S1 to either ground or Vin2. In other words, the leakage current from S1 is isolated from the tap point Rtap. An advantage of the system 300 is that it may cause less corruption of the voltage level at node Vout, due to leakage current of S1, as compared to system 100. However, the architecture of system 100 may be acceptable for various applications.

Just as in system 100, system 300 uses a different value of RB for each of the different gain settings, and each of the different gain settings corresponds to a different sum of resistance value of RA plus resistance value of RB. Therefore, system 300 may allow for designs that keep the feedback pole, as measured in megahertz, larger than a desired bandwidth of operation of the amplifier.

For a gain of two, control circuit 110 turns switch S1 on, turns S8 on, and turns S7 on. The other switches are turned off. The current path includes R9, S1, S8, R8, and S7. The resistive portion RB includes R9, the resistive portion RA includes R8. Resistors R10-R11 are bypassed. The resistor ladder that includes R12-R16 is also bypassed.

For a gain of four, control circuit 110 turns switch S1 on, turns S9 on, and turns S7 on. The other switches are turned off. The current path includes R9, S1, R10, R11, and S7. The resistive portion RB includes R9, R10, and the resistive portion RA includes R11.

For a gain of eight, control circuit 110 turns on switches S2, S5, and S7. The other switches are off. The resistive portion RB includes resistors R12, R13, and the resistive portion RA includes resistor R8. The resistors R14-R16 are bypassed. The resistor ladder that includes switch S1 is not used at all. For the gain settings 8-32, the respective current paths extend from Vout to RB, to RA, and to ground.

For a gain of 16, control circuit 110 turns on switches S3, S5, and S7. The other switches are off. The resistive portion RB includes resistors R12-R15, and the resistive portion RA includes resistor R8. The resistor R16 is bypassed, and the resistor ladder that includes switch S1 is not used at all.

For a gain of 32, control circuit 110 turns on switches S5 and S7, and all other switches are off. The resistive portion RB includes resistors R12-R16, and the resistive portion RA includes resistor R8. No resistors in the resistor ladder having R12-R16 are bypassed. The resistor ladder that includes switch S1 is not used at all.

The inverting gain settings may be achieved by turning switch S6 on and turning switch S7 off, but otherwise controlling the switches S1-S3, S5, S8, and S9, as described above with respect to the noninverting gain settings. The respective current paths are from Vout to RB, to RA, to Vin2.

Once again, the sum of the resistive value of RA plus the resistive value of RB changes at each gain setting. A further advantage of using a separate resistor ladder for switch S1 may include isolating a parasitic capacitance attributable to switch S1. For instance, the parasitic capacitance attributable to switch S1 may add a feedback pole when switch S1 is turned off. However, the additional feedback pole has negligible or no effect because it is isolated from the tap point Rtap when switches S1, S8, S9 are off.

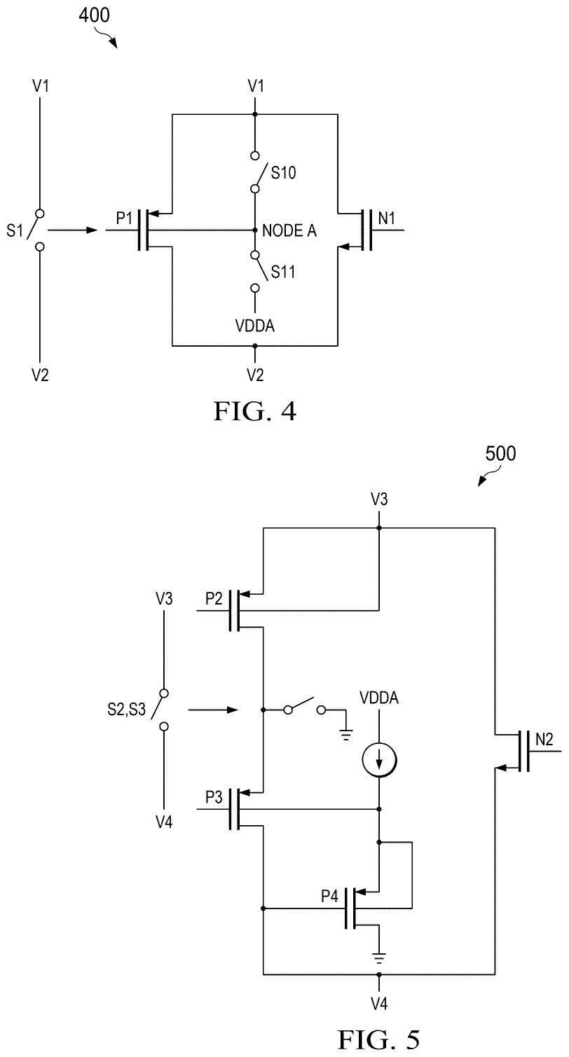

FIG. 4 is an illustration of an example architecture 400 for implementing the switch S1, according to various embodiments. As noted above, it may be desirable in some applications to size the transistors of the various switches so as to balance semiconductor die area and impedance. For instance, in one example, it may be desirable to keep an impedance of a given switch to less than 1% of the resistive value of RB. Of course, different applications may have different requirements, so that 1% is just an example. Further as noted above, while it might seem desirable to reduce impedance by increasing the size of transistors, the size of transistors may quickly overwhelm the silicon die area budget.

Various embodiments herein may implement switch S1 in a way that balances silicon die area budget and impedance. Architecture 400 includes an N channel metal oxide semiconductor (NMOS) transistor N1 implemented in parallel with a P channel metal oxide semiconductor (PMOS) transistor P1. The source terminal of P1 is coupled to the drain terminal of N1 at node V1. In this example, node V1 may correspond to the node between RA and RB of FIG. 1 and where S1 is coupled to resistor R9 in FIG. 3.

Further in this example, the drain terminal of P1 may be coupled to the source terminal of N1 at node V2. The node V2 may correspond to the node where switch S1 is coupled to switch S4 and FIG. 1 or where switch S1 is coupled to switch S8 in FIG. 3. Node A is coupled to the body terminal of transistor P1. Switch S10 couples Node A to V1, and switch S11 couples Node A to VDDA. VDDA correspond to a different voltage than either Vin1 or Vin2. VDDA may be include any voltage appropriate to bias the body terminal of transistor P1.

In the example architecture 400, P1 and N1 are arranged in parallel so that the parallel impedance sum (N1|P1) of switch S1 is less than an impedance attributable to either P1 or N1 separately. Furthermore, the control circuit 110 may control P1 and N1 so that they are on at the same time during an on state of switch S1 and off at the same time during an off state of switch S1. The control circuit 110 may further control S10 and S11 so that when S1 is on, S10 is on and S11 is off, when S1 is off, S10 is off and S11 is on.

In one example, the dimensions of transistor P1 may be 192/0.4, where the length is 192 length units (e.g., micrometers), and the length is 0.4 length units. During a design phase of architecture 400, an engineer may use a simulator to determine appropriate dimensions for P1 and N1, and each different application may have different requirements. It is understood that the dimensions of this implementation are an example that may be adapted to other applications.

FIG. 5 is an illustration of an example architecture 500 for implementing the switches S2 and/or S3, according to various embodiments. In some embodiments, the transistors of S1 may be made larger than the transistors of either of switches S2 or S3 because of the larger amount of resistance that the system uses to bypass via switch S1 relative to that bypassed by switches S2 and S3. For instance, in one example, transistors P2 and P3 may be sized as 16/0.4, and transistor N2 may be sized as 10/05. However, the scope of implementations may be adapted for other dimensional values as appropriate.

Thus, in some applications, it may be acceptable to use relatively smaller transistors for switches S2 and S3 because the increase in impedance attributable to those transistors may be acceptable. However, the scope of implementations may include embodiments that use architecture 400 for switches S2 and S3 and/or uses architecture 500 for switch S1, so long as impedance falls within an acceptable range over process, temperature, and operating voltage.

In this example, transistors P2, P3, and P4 are PMOS transistors. Transistor N2 is an NMOS transistor. A source of transistor P2 is coupled to a drain of transistor N2 at node V3. Node V3 may correspond to the node between resistors R3 and R4 (S2), the node between resistors R4 and R5 (S3) in FIG. 1 or, in FIG. 3, the node between resistors R13 and R14 (S2) or the node between resistors R15 and R16 (S3).

The drain of transistor P3 is coupled to the source of transistor N2 at node V4. Node V4 may correspond to the nodes coupling S5 to R8 in both FIGS. 1, 3. The body terminal of transistor P3 is coupled to the drain terminal of transistor P3 through transistor P4. Also, the gate terminal of transistor P4 is coupled to the drain terminal of transistor P3. The arrangement of transistor P4 with respect to P3 ties the body voltage of transistor P3 to the drain voltage of transistor P3 through transistor P4, thereby reducing a body-to-drain voltage difference. When switch S2 or S3 is turned off, the reduced body to drain voltage of transistor P3 may result in less leakage current.

The control circuit 110 may control transistors P2, P3, P4, and N2 so that when switch S2 or switch S3 is on, those transistors are on as well. Therefore, the resistance attributable to the transistors P2, P3, and N2 is based on the parallel resistance sum (P2+P3)|N2. The control circuit 110 may control transistors P2, P3, and N2 to be off at the same time when switch S2 or S3 is off. The control circuit 110 may adjust a state of P4 as desired to reduce the body-to-drain voltage difference of transistor P3.

The resistor ladders of FIGS. 1 and 3 may be arranged having the tap point (Rtap) and the amplifier output node (Vout) as illustrated in FIG. 2. Although not shown in FIG. 2, the amplifier output may be used for any of a variety of purposes. In one example, the amplifier output may be coupled to an analog-to-digital converter (ADC), which converts the signal at Vout to a plurality of digital bits. Continuing with the example, the input voltages (Vin1, Vin2) may be derived from a radio frequency (RF) device, such as might be used to receive signals over the air or over a wired connection.

Such devices may be built on one or more semiconductor dies. For example, the programmable gain amplifier itself (including op amp 202 and control circuit 110) may be built on a system on-chip (SOC) with a multitude of other digital and/or analog components. The one or more semiconductor dies may be implemented in a semiconductor package.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A programmable gain amplifier comprising:
an amplifier having an inverting input, a noninverting input, and an amplifier output;
a set of resistors coupled between a first node and a second node, wherein the first node is coupled to the amplifier output;
a first switch coupled between the second node and ground;
a first current path between a third node in the set of resistors and a tap point, the first current path including a second switch;
a second current path between a fourth node in the set of resistors and the tap point, the second current path including a third switch; and
a feedback path coupled between the tap point of the set of resistors and the inverting input of the amplifier;
wherein the set of resistors includes a first resistor coupled between the third node and the fourth node.

2. The programmable gain amplifier of claim 1, further comprising:
a third current path coupled between a fifth node in the set of resistors and the tap point, the third current path including a fourth switch, wherein the fifth node in the set of resistors is between the third node and the first node.

3. The programmable gain amplifier of claim 2, further comprising:
a fifth switch coupled between the tap point and a sixth node in the set of resistors; and
a sixth switch coupled between the tap point and a seventh node in the set of resistors, wherein:
the set of resistors includes the first resistor coupled between the sixth node and the seventh node;
the third current path is coupled to the tap point via the fifth switch; and
the first current path and second current path are coupled to the tap point via the sixth switch.

4. The programmable gain amplifier claim 2, wherein the fourth switch has a larger dimension than a corresponding dimension in either of the second switch or the third switch.

5. The programmable gain amplifier of claim 2, wherein the fourth switch comprises an N channel metal oxide semiconductor (NMOS) transistor and a P channel metal oxide semiconductor (PMOS) transistor in parallel.

6. The programmable gain amplifier of claim 1, wherein the second switch comprises an N channel metal oxide semiconductor (NMOS) transistor and a P channel metal oxide semiconductor (PMOS) transistor, wherein a drain of the PMOS transistor is coupled to a source of the NMOS transistor, further wherein a body terminal of the PMOS transistor is coupled to the drain of the PMOS transistor through a second PMOS transistor.

7. The programmable gain amplifier of claim 1, further comprising a fourth switch coupled between the second node and an input voltage node.

8. The programmable gain amplifier of claim 1, wherein the amplifier output is coupled to an analog-to-digital converter.

9. The programmable gain amplifier of claim 1, further comprising:
a third current path coupled between the first node and the second node of the set of resistors, the third current path including a fourth switch and another set of resistors coupled in parallel to the set of resistors.

10. The programmable gain amplifier of claim 9, further comprising:
a fifth switch coupled between a first terminal of a first resistor of the another set of resistors and the tap point; and
a sixth switch coupled between a second terminal of the first resistor and the tap point.

11. A circuit comprising:
a set of resistors coupled in series having a first node coupled to an amplifier output and a second node coupled to ground;
a feedback path coupling a tap point of the set of resistors to an amplifier input; and
a first switch, a second switch, and a third switch, wherein:
the first switch is coupled between the second node of the set of resistors and the ground,
a first current path is coupled between a third node of the set of resistors and the tap point, the first current path including the second switch, wherein the first current path is parallel to a first portion of the set of resistors,
a second current path is coupled between a fourth node in the set of resistors and the tap point, the second current path including the third switch, wherein the second current path is parallel to a second portion of the set of resistors, and
the set of resistors includes a first resistor coupled between the third node and the fourth node.

12. The circuit of claim 11, further comprising:
a fourth switch implemented in a third current path, wherein the third current path couples a fifth node in the set of resistors to the tap point, the third current path being parallel to a third portion of the set of resistors.

13. The circuit of claim 12, wherein the fourth switch has a larger dimension than a corresponding dimension in either of the second switch or the third switch.

14. The circuit of claim 11, further comprising:
a third current path coupling the first node of the set of resistors to the second node of the set of resistors, the third current path including a fourth switch and an additional set of resistors in parallel to the set of resistors;
a fifth switch coupling a first terminal of a second resistor in the additional set of resistors to the tap point; and
a sixth switch coupling a second terminal of the second resistor in the additional set of resistors to the tap point.

15. A programmable gain amplifier comprising:
an amplifier having a noninverting input, an inverting input, and an amplifier output;
a set of resistors coupled in series between the amplifier output and ground;
a plurality of switches; and
a control circuit coupled to the plurality of switches, wherein the control circuit is further configured to:
control a first switch, of the plurality of switches, to complete a first current path from a first node in the set of resistors to a tap point, wherein the tap point divides a first resistive portion (RA) of the set of resistors between the tap point and ground and a second resistive portion (RB) of the set of resistors between the tap point and the amplifier output;
control a second switch, of the plurality of switches, to complete a second current path from a second node in the set of resistors to the tap point; and
change a sum of resistance of RA plus resistance of RB by turning on the first switch and turning off the second switch and by turning off the first switch and turning on the second switch.

16. The programmable gain amplifier of claim 15, wherein the amplifier is coupled to a first power supply at its noninverting input, and wherein the set of resistors is further coupled to a second power supply, wherein the set of resistors is coupled to ground by a third switch of the plurality of switches and is coupled to the second power supply by a fourth switch of the plurality of switches, further wherein the control circuit is configured to control the third switch and the fourth switch to provide either inverting gain or noninverting gain.

17. The programmable gain amplifier of claim 15, wherein the control circuit is further configured to:
control a fifth switch, of the plurality of switches, to complete a third current path from a node point in the set of resistors to the tap point, wherein the third current path bypasses the first current path and the second current path; and
change the sum of resistance of RA plus resistance of RB by selecting among the first switch, the second switch, and the fifth switch.

18. The programmable gain amplifier of claim 17, wherein the fifth switch has a larger dimension than a corresponding dimension in either of the first switch or the second switch.

19. The programmable gain amplifier of claim 17, wherein the third current path comprises an additional set of resistors.

20. The programmable gain amplifier of claim 19, wherein the control circuit is further configured to:
direct leakage current from the fifth switch, during a time in which the fifth switch is turned off, to ground, including isolating the leakage current from the tap point.
